(19) United States
(12) Patent Application Publication
(10) Pub. No.: US 2011/0134403 A1
(43) Pub. Date: Jun. 9, 2011

(54) MICROLITHOGRAPHIC PROJECTION EXPOSURE APPARATUS

(75) Inventors: Heiko Feldmann, Schwaebisch Gmuend (DE); Alexander Epple, Aalen (DE); Vladan Blahnik, Aalen (DE)

(73) Assignee: CARL ZEISS SMT AG, Oberkochen (DE)

(21) Appl. No.: 11/573,628

(22) PCT Filed: Sep. 16, 2005
(86) PCT No.: PCT/EP2005/009966

§ 371 Date: Jun. 15, 2007

Related U.S. Application Data
(60) Provisional application No. 60/615,988, filed on Oct. 5, 2004.

(51) Int. Cl. G03B 27/52; G03F 7/20

(52) U.S. Cl. 355/53; 430/325

(57) ABSTRACT

A microlithographic projection exposure apparatus contains a projection objective, whose last optical element on the image side is a dry terminating element that has no refractive power and is designed for dry operation of the projection objective. According to the invention, the projection exposure apparatus furthermore contains an immersion terminating element that has no refractive power and is designed for immersed operation of the projection objective. The immersion terminating element is replaceable with the dry terminating element. Preferably, the dry terminating element and/or the immersion terminating element is composed of a plurality of plates, which are made of materials having different refractive indices.

### CROSS-REFERENCE TO RELATED APPLICATIONS

This application claims benefit of U.S. provisional application 60/615,988 filed Oct. 5, 2004.

### BACKGROUND OF THE INVENTION

1. Field of the Invention

The invention relates to microlithographic projection exposure apparatus, such as those used for the production of large-scale integrated electrical circuits and other microstructured components.

2. Description of the Prior Art

Integrated electrical circuits and other microstructured components are conventionally produced by applying a plurality of structured layers on a suitable substrate which, for example, may be a silicon wafer. In order to structure the layers, they are first covered with a photoresist which is sensitive to light of a particular wavelength range, for example light in the deep ultraviolet (DUV) spectral range. The wafer coated in this way is subsequently exposed in a projection exposure apparatus. A pattern of diffracting structures, which is arranged on a mask, is thereby projected onto the photoresist with the aid of a projection objective. Since the imaging scale is generally less than 1, such projection objectives are often also referred to as reduction objectives.

After the photoresist has been developed, the wafer is subjected to an etching process so that the layer becomes structured according to the pattern on the mask. The remaining photoresist is then removed from the other parts of the layer. This process is repeated until all the layers have been applied on the wafer.

One of the essential aims in the development of the projection exposure apparatus used for production is to be able to lithographically define structures with smaller and smaller dimensions on the wafer. Small structures lead to high integration densities, and this generally has a favorable effect on the performance of the micro-structured components produced with the aid of such apparatus.

The size of the structures which can be defined depends primarily on the resolution of the projection objective being used. Since the resolution of the projection objectives is proportional to the wavelength of the projection light, one way of increasing the resolution is to use projection light with shorter and shorter wavelengths. The shortest wavelengths used at present are in the deep ultraviolet (DUV) spectral range, namely 193 nm and 157 nm.

Another way of increasing the resolving power is based on the idea of introducing an immersion liquid with a high refractive index into an intermediate space which remains between a last lens on the image side of the projection objective and the photoresist. Projection objectives which are specially designed for immersed operation, and which are therefore also referred to as immersion objectives, can achieve numerical apertures of more than 1, for example 1.3 or 1.4. Immersed operation, however, is also advantageous with less high numerical apertures. For example, immersion has a favorable effect on the depth of focus. The greater the depth of focus is, the less stringent are the requirements for exact positioning of the wafer in the image plane of the projection objective.

Carrying out immersed operation, however, requires considerable extra outlay on construction and process technology. For example, it is necessary to ensure that the optical properties of the immersion liquid are spatially homogeneous, at least inside the volume exposed to the projection light, and constant as a function of time.

It has therefore been considered expedient that the projection exposure apparatus should be operated in immersion only during particularly critical process steps, but should otherwise be operated dry as has previously been conventional. Because of this, admittedly, it is not possible to increase the numerical aperture since this requires a different configuration of the projection objective. Other advantages of immersed operation, for instance the higher depth of focus, can nevertheless be achieved even with a projection objective which is configured per se for dry operation. The projection objective is used without an immersion liquid in the less critical process steps, so that the exposure of the wafer is simplified considerably and, as a general rule, can be carried out more rapidly.

However, the introduction of an immersion liquid into the intermediate space between the last lens on the image side and the photoresist will affect the imaging by the projection objective. Previously, therefore, it has been necessary to carry out substantial reconfiguration of the projection objective for a change between dry operation and immersed operation. Such reconfiguration is described in US 2004/0109237 assigned to the applicant.

### SUMMARY OF THE INVENTION

It is an object of the invention to provide a projection exposure apparatus with which such a change from dry operation to immersed operation, and vice versa, can be carried out in a more straightforward way.

This object is achieved by a microlithographic projection exposure apparatus having a projection objective whose last optical element on the image side is a dry terminating element that has no refractive power and is designed for dry operation of the projection objective. According to the invention, the projection exposure apparatus comprises an immersion terminating element that has no refractive power and is designed for immersed operation of the projection objective, wherein the immersion terminating element is replaceable with the dry terminating element (TE; TE2; TE3).

The invention is based on the idea that the immersion liquid has the optical effect of a plane-parallel plate. In projection objectives whose last optical element on the image side is a terminating element having no refractive power, the function of the immersion liquid can be fulfilled by such a terminating element when changing from immersed operation to dry operation.

The projection exposure apparatus according to the invention thus makes it possible to convert between dry operation and immersed operation merely by replacing the terminating element of the projection exposure apparatus. More extensive reconstruction or reassembly, especially concerning the optical elements inside the projection objective, is not necessary. Although it is also possible to carry out additional tuning with the aid of manipulators known per se, which act on optical elements inside the projection objective, this is generally required only for particularly high-aperture projection objectives.

The immersion liquids available to date have refractive indices which, although higher than the refractive indices of gases, are nevertheless different from the refractive indices of the materials used to make the transparent optical elements of the projection objectives. When changing from immersed operation to dry operation, therefore, it is not possible to replace the immersion liquid with a plane-parallel plate which has the same thickness and exactly the same refractive index as the immersion liquid. A terminating element designed for dry operation, which will be referred to here as a dry terminating element, will admittedly in general be thicker than an immersion terminating element designed for immersed operation. The refractive index which the dry terminating element should have, in order to fulfill the function of the immersion liquid as well as possible, needs to be determined by means of numerical optimization methods.

The design of the terminating elements is furthermore made difficult by the fact that only a few materials are currently available which are sufficiently transparent at the projection wavelengths used. The refractive indices of the terminating elements are therefore not freely selectable. In view of this, it is favorable for the dry terminating element and/or the immersion terminating element to contain at least two plane-parallel plates, which are made of materials having different refractive indices. This provides additional degrees of freedom which can be varied during optimization.

In principle, it is possible to start on the basis of an existing projection objective which is designed for dry operation. The immersion terminating element to be designed for immersed operation must then have a smaller thickness than the dry terminating element, if the same material is used for both terminating elements. In this case, a significant improvement of the imaging quality can be achieved if a part of the immersion terminating element is made of a material having a different refractive index. A further improvement of the imaging quality can be achieved by subdividing the immersion terminating element into more than two plates, especially for high-aperture projection objectives.

In this context, it is particularly preferable that the dry terminating element is made of a material having a first refractive index, and a first plate of the immersion terminating element is made of a material having the first refractive index and a second plate of the immersion terminating element is made of a material having a second refractive index, which is higher than the first refractive index. In this way, it is possible to correct very substantially a zonal spherical aberration which grows with increasing numerical aperture. For example, if the dry terminating element is made of calcium fluoride which has a refractive index of 1.47 at a projection light wavelength of 193 nm, then the immersion terminating element may comprise a thicker plate of calcium fluoride and a thinner plate of quartz glass, which has a refractive index of about 1.51 at the said wavelength.

It is more favorable, however, not to start on the basis of an already existing projection objective. This is because not only the terminating elements but also the other parts of the projection objective can then be included in an optimization. The number of degrees of freedom for optimization is increased considerably in this way, which generally leads to a better approximation of a target parameter. Consequently, the dry terminating element and optionally also the immersion terminating element may comprise a plurality of plane-parallel plates which are made of materials having different refractive indices.

### BRIEF DESCRIPTION OF THE DRAWINGS

Other advantages and features will be found in the following description of the exemplary embodiments, with reference to the drawings in which:

FIG. 1 shows a meridian section through a microlithographic projection exposure apparatus according to a first exemplary embodiment of the invention, in a schematic representation which is not true to scale;

FIG. 2a shows an enlarged detail of the image-side end of the projection objective shown in FIG. 1, during dry operation;

FIG. 2b shows the image-side end of the projection objective according to FIG. 2a, but during immersed operation;

FIG. 3a shows a detail, corresponding to FIG. 2a, of a projection objective according to a second exemplary embodiment of the invention, during dry operation;

FIG. 3b shows the image-side end of the projection objective according to FIG. 3a, but during immersed operation;

FIG. 4a shows a detail, corresponding to FIG. 2a, of a projection objective according to a third exemplary embodiment of the invention, during dry operation;

FIG. 4b shows the image-side end of the projection objective according to FIG. 4a, but during immersed operation.

### DESCRIPTION OF PREFERRED EMBODIMENTS

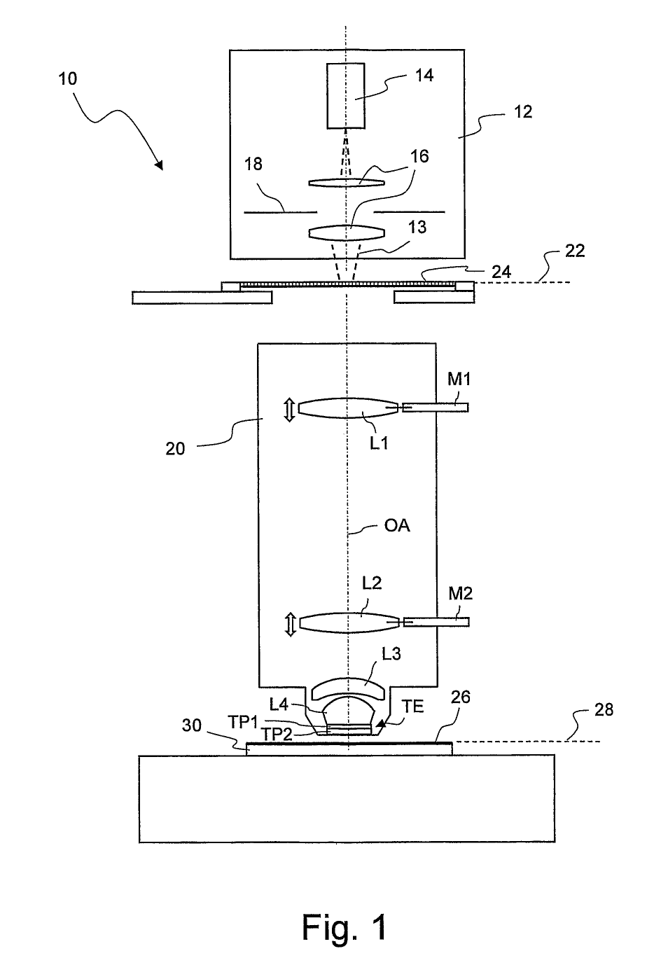

FIG. 1 shows a meridian section through a microlithographic projection exposure apparatus, denoted overall by 10, in a highly simplified representation which is not true to scale, during dry operation. The projection exposure apparatus 10 has an illumination device 12 for the generation of projection light 13, which comprises a light source 14, illumination optics indicated by 16 and a diaphragm 18. In the exemplary embodiment which is represented, the projection light 13 has a wavelength of 193 nm.

The projection exposure apparatus 10 furthermore includes a projection objective 20 which contains a multiplicity of lenses, only some of which denoted by L1 to L4 are indicated by way of example in FIG. 1 for the sake of clarity. The projection objective 20 also contains a terminating element TE as the last optical element that has plane-parallel surfaces and therefore has no refractive power. The terminating element TE terminates the projection objective 20 on the image side and comprises a first and a second plate TP1 and TP2, respectively, which are likewise plane-parallel.

The lenses L1 to L4 are made of quartz glass having a refractive index of about 1.51 at the wavelength 193 nm. Nevertheless, other materials which have sufficient optical transparency at the wavelength of the projection light 13 may also be selected as the material, for example calcium fluoride (CaF₂) or barium fluoride (BaF₂).

The projection objective 20 is used to project a reduced image of a mask 24, which is arranged in an object plane 22 of the projection objective 20, onto a photosensitive layer 26. The layer 26, which may, for example, consist of a photoresist, is arranged in an image plane 28 of the projection objective 20 and is applied on a support 30. The support 30 may, for example, be a silicon wafer.

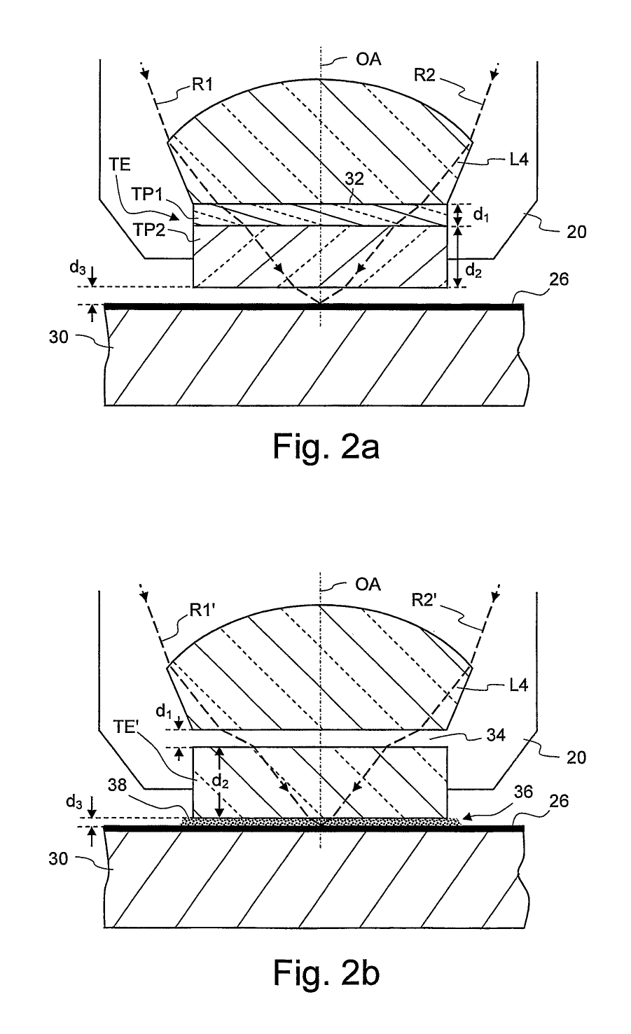

FIG. 2a gives a simplified representation of the image-side end of the projection objective 20 in an enlarged detail. It can be seen therein that the two plates TP1 and TP2 are joined together seamlessly, for example by direct contact bonding. The plates TP1 and TP2 may nevertheless be joined together in a different way or held separately from each other at the intended position by corresponding holders. It is furthermore possible to arrange the two plates TP1, TP2 at a distance from each other, since displacing a plane-parallel plate along an optical axis OA of the projection objective 20 does not affect the imaging by the projection objective 20.

It can furthermore be seen in FIG. 2a that the entire terminating element TE joins seamlessly with the plane surface 32 on the image side of the lens L4. Here again, the connection between the lens L4 and the first plate may be achieved by direct contact bonding or in a different way. It is furthermore possible to hold the terminating element TE at a distance from the last lens L4 by using a suitable holder.

In the first exemplary embodiment represented, the first plate TP1 is made of barium fluoride (BaF₂), which has a refractive index of about 1.60 at a wavelength of 193 nm. The second plate TP2 is made of calcium fluoride (CaF₂), the refractive index of which is about 1.47 at this wavelength. The thickness d₁ of the first plate TP1 is about 5.76 mm and the thickness d₂ of the second plate TP2 is about 21.82 mm. The distance d₃ between the second plate TP2 and the photosensitive layer 26 is 6 mm. The optical effect of the lens L4 and the terminating element TE is indicated by rays R1 and R2 represented as dashes.

FIG. 2b shows the image-side end of the projection objective 20 during immersed operation. To change from the dry operation shown in FIG. 2a to the immersed operation shown in FIG. 2b, the terminating element TE designed for dry operation has been replaced with another terminating element TE′, which is designed for immersed operation. The terminating element TE′ designed for immersed operation is formed as a plane-parallel plate made of quartz glass having a thickness d₂ of about 24.57 mm. The terminating element TE′ designed for immersed operation is arranged so that a gas-filled intermediate space 34, the thickness d₁ of which is about 6 mm, remains above the terminating element TE′. A second intermediate space 36, which has a thickness d₃=3 mm, remains between the terminating element TE′ and the photosensitive layer 26. The second intermediate space 36 is filled with an immersion liquid 38, which is highly pure deionised water in the exemplary embodiment represented. The refractive index of the water is about 1.38 at this wavelength.

Here again, rays R1′ and R2′ show the optical effect of the lens L4 and the terminating element TE′ during immersed operation.

The imaging properties of the projection objective 20 must not be degraded, or not intolerably degraded, when changing between the dry operation shown in FIG. 2a and the immersed operation shown in FIG. 2b. If such a change is not meant to require reconfiguration of the entire projection objective 20, but merely replacement of the terminating element TE designed for dry operation with the terminating element TE′ designed for immersed operation, then the terminating elements TE, TE′ and the projection objective 20 need to be suitably optimized with respect to their optically critical parameters.

The number and thicknesses and materials of the plates of which the terminating elements TE and TE′ are composed, in particular, are available for this in the case of the two terminating elements TE, TE′. In the case of the projection objective 20, it is generally sufficient to keep section widths between the lenses variable.

The target parameter for the optimization is preferably the imaging quality of the projection objective 20. For example, the deviations of the wavefront from a plane wave in a pupil plane of the projection objective 20 are a measure of this. In general, these deviations of the wavefront are described by a superposition of polynomials which form an orthogonal function system. It is particularly common to use Zernike polynomials for this purpose, since some of these polynomials can be assigned to particular imaging errors of different orders which are known per se. The target parameter for the optimization may, for example, then be a merit function which contains the coefficients of a plurality of Zernike polynomials, and which should be as small as possible. Numerical methods used to determine an optimum parameter set are known per se in the prior art, so they need not be explained here.

As mentioned above, the optimization does not have to be restricted to the terminating elements TE, TE′, but may also include the other optical elements of the projection objective 20. This is related to the fact that although the terminating elements TE, TE′ do not have a refractive power, they nevertheless exert an optical effect and, for example, introduce a spherical aberration into the system. Modifications of the terminating elements in the scope of optimization therefore generally entail adaptive measures with respect to the other optical elements of the projection objective 20. This may, for example, involve modifications of section widths of individual optical elements.

The greater is the number of materials with different refractive indices, of which the terminating elements TE, TE′ are composed, the easier it will be to find a parameter set with which the imaging properties of the projection objective 20 vary only little when changing between dry operation and immersed operation. This applies in particular for projection objectives 20 having high numerical apertures, for example 0.9 or more. On the other hand, each additional optical element represents a potential source of error and generally increases the production costs. In view of this, when changing from dry operation to immersed operation and vice versa, it may therefore be expedient to carry out additional adaptive measures with the aid of manipulators, known per se, which engage on individual optical elements of the projection objective 20.

Such manipulators, denoted by M1 and M2, are schematically shown in FIG. 1 for the lenses L1 and L2. The manipulators M1, M2 may, for example, be designed so that they can displace the lenses L1, L2 along the optical axis OA. Since such displacing movements can be readily carried out during a projection pause, which is in any case necessary when changing between dry operation and immersed operation or vice versa, the outlay for such additional corrective measures is minor.

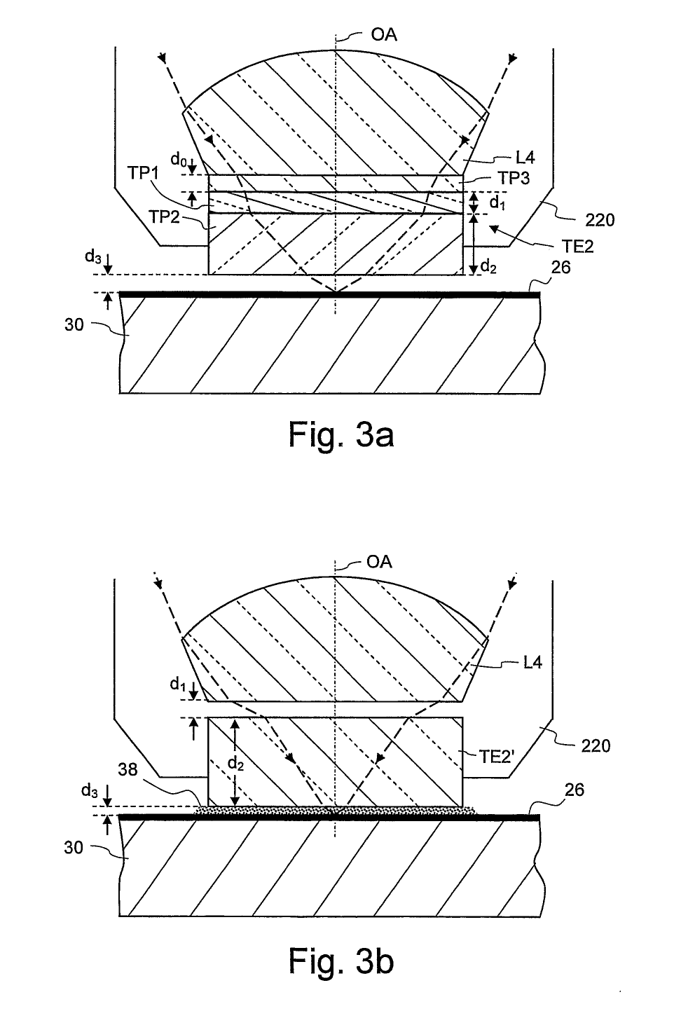

FIGS. 3a and 3b show a second exemplary embodiment with a projection objective 220, in representations analogous to FIGS. 2a and 2b. In relation to the first exemplary embodiment shown in FIGS. 2a and 2b, the second exemplary embodiment differs only in that the terminating element TE2′ designed for immersed operation has a thickness d₂ which is 5 mm greater than the thickness of the terminating element TE′ shown in FIG. 2b. To compensate for this, the terminating element TE2 designed for dry operation also contains a third plate TP3 in addition to the plates TP1 and TP2. With respect to its material and thickness, the third plate TP3 corresponds exactly to the enlargement of the terminating element TE2′ designed for immersed operation, i.e. it is likewise made of quartz glass and has a thickness d₀ of 5 mm. The additional third plate TP3 of quartz glass changes the optical effect of the terminating element TE2, so that it is necessary to adapt the other optical elements of the projection objective 20.

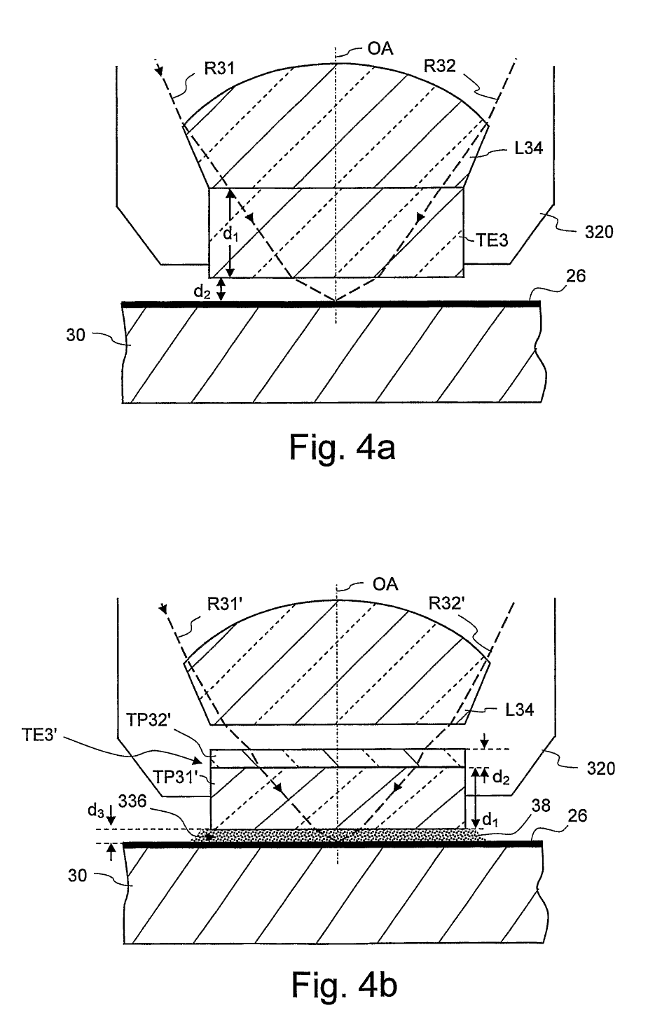

FIGS. 4a and 4b show a third exemplary embodiment of the invention, likewise in a representation analogous to FIGS. 2a and 2b.

The projection objective according to the third exemplary embodiment, denoted by 320, is a conventional projection element designed for dry operation with a terminating element TE3. The last lens on the image side with a positive refracting power, denoted here by L34, is made of calcium fluoride in this exemplary embodiment like the terminating element TE3. The thickness d₁ of the terminating element TE3 is 12.80 mm.

For the changeover to immersed operation, the terminating element TE3 is replaced with a terminating element TE3′, which is composed of a first plate TP31′ and a second plate TP32′. The first plate TP31′ has a thickness d₁ of 7.64 mm and is made of calcium fluoride. The second plate TP32′ has a thickness d₂ of 3.20 mm and is made of quartz glass. The intermediate space 336 between the terminating element TE3′ and the photosensitive layer 26, which is filled with immersion liquid 38, has a thickness d₃ of 2 mm.

In contrast to the first and second exemplary embodiments, the optimization here is based on an already existing dry objective 320 which is meant to remain unmodified. The degrees of freedom available for the optimization are now only the number and thicknesses and materials of the plates of which the terminating element TE3′ to be designed for immersed operation is composed. Owing to this reduced number of degrees of freedom, in such a case it is more difficult to determine a terminating element TE3′ designed for immersed operation, with which particular imaging properties of the projection objective 320 are at most insubstantially degraded when it replaces the terminating element TE3 designed for dry operation. The additional use of manipulators M1, M2 is therefore more necessary in the third exemplary embodiment than in the previously described exemplary embodiments, at least for high numerical apertures. On the other hand, the third exemplary embodiment has the advantage that it is possible to start with an already existing and proven projection objective 320.

Here again, it is generally possible to improve the imaging properties with an increasing number of plates, of which the terminating element TE3′ designed for immersed operation is composed. In general, however, a significant improvement of the imaging properties is already achieved when the terminating element TE3′ designed for immersed operation consists not just of a single plate, but comprises two plates TP31′, TP32′, as is the case in the third exemplary embodiment represented in FIGS. 4a, 4b. If the refractive index of the immersion liquid 38 is less than the refractive index of the terminating element TE3 designed for dry operation, which ought generally to be the case, then one plate—here the first plate TP31′—may be made of the same material as the terminating element TE3 designed for dry operation. The additional plate—here the second plate TP32′—should then be made of a material which has a higher refractive index than the first plate TP31′. With a corresponding selection of the thicknesses of the two plates TP31′, TP32′, a zonal spherical aberration can then be corrected very substantially.

It is to be understood that the above description is not meant to imply any limitation, and that a very wide variety of variants are possible. For example, the invention may also be used advantageously in so-called maskless projection exposure apparatus. In these apparatus, masks with dynamically variable structures are used instead of conventional masks with rigidly predetermined structures. Such dynamic masks usually contain micro-electromechanical systems (MEMS), for instance in the form of micro-mirror arrays as described for example in US 2004/0130564 A1. Other solutions have also been disclosed besides this, for example masks which are composed of individually illuminable microlenses, cf. for instance US 2004/0124372 A1.

1. A microlithographic projection exposure apparatus, comprising:
a) a projection objective whose last optical element on the image side is a dry terminating element that has no refractive power and is designed for dry operation of the projection objective, and
b) an immersion terminating element that has no refractive power and is designed for immersed operation of the projection objective, wherein the immersion terminating element is replaceable with the dry terminating element.

2. The projection exposure apparatus according to claim 1, wherein the dry terminating element and the immersion terminating element are both plane-parallel plates.

3. The projection exposure apparatus according to claim 2, wherein the dry terminating element comprises at least two plane-parallel plates made of materials having different refractive indices.

4. The projection exposure apparatus according to claim 3, wherein the dry terminating element comprises a plate made of barium fluoride and a plate made of calcium fluoride.

5. The projection exposure apparatus according to claim 4, wherein the dry terminating element additionally comprises a plate made of quartz glass.

6. The projection exposure apparatus according to claim 4, wherein the immersion terminating element is made of quartz glass.

7. The projection exposure apparatus according to claim 2, wherein the immersion terminating element contains at least two plane-parallel plates that are made of materials having different refractive indices.

8. The projection exposure apparatus according to claim 7, wherein
a) the dry terminating element is made of a material having a first refractive index,
b) a first plate of the immersion terminating element is made of a material having the first refractive index, and wherein
c) a second plate of the immersion terminating element is made of a material having a second refractive index, which is higher than the first refractive index.

9. The projection exposure apparatus according to claim 7, wherein the immersion terminating element comprises a plate made of calcium fluoride and a plate made of quartz glass.

10. The projection exposure apparatus according to claim 7, wherein the immersion terminating element also comprises at least one further plate made of another material.

11. The projection exposure apparatus according to claim 1, wherein the dry terminating element and the immersion terminating element are configured such that the projection objective does not need to be modified for a change between dry operation and immersed operation.

12. The projection exposure apparatus according to claim 1, wherein the dry terminating element and the immersion terminating element are configured so that the projection objective needs to be adjusted but not reconfigured for a change between dry operation and immersed operation.

13. The projection exposure apparatus according to claim 12, comprising manipulators for adjusting the projection objective.

14. The projection exposure apparatus according to claim 1, wherein the projection objective has a numerical aperture of more than 0.6.

15. A method for changing over a projection objective of a microlithographic projection exposure apparatus from dry operation to immersed operation, the method comprising:
a) Providing a projection objective whose last optical element on the image side is a dry terminating element having no refractive power; and
b) Replacing the dry terminating element with an immersion terminating element that has no refractive power and which is designed for immersed operation of the projection objective.

16. A method for the microlithographic production of microstructured components, steps the method comprising:
a) Providing a support, on which a layer of a photosensitive material is applied;
b) Providing a mask, which contains structures to be imaged;
c) Providing a projection exposure apparatus according to claim 1; and
d) Projecting at least a part of the mask onto a region on the layer with the aid of the projection exposure apparatus.

17. (canceled)

18. A microstructured component, produced by a method according to claim 16.
